(19) United States
(12) Patent Application Publication
(10) Pub. No.: US 2025/0010341 A1
(43) Pub. Date: Jan. 9, 2025

(54) SUBSTRATE PROCESSING APPARATUS AND SUBSTRATE PROCESSING METHOD

(71) Applicant: Tokyo Electron Limited, Tokyo (JP)

(72) Inventors: Takanori Obaru, Koshi City (JP); Kento Kurusu, Koshi City (JP)

(21) Appl. No.: 18/761,581

(22) Filed: Jul. 2, 2024

(30) Foreign Application Priority Data
Jul. 4, 2023 (JP) 2023-110014

(51) Int. Cl. B08B 1/40; B08B 1/36; B08B 3/10; B08B 11/02; B08B 13/00

(52) U.S. Cl. CPC B08B 1/40; B08B 1/36; B08B 3/10; B08B 11/02; B08B 13/00

(57) ABSTRACT

A substrate processing apparatus includes a processor configured to process a substrate with a processing liquid. The processor has a holder configured to hold the substrate horizontally. The holder includes a first holder configured to come into contact with a center of a bottom surface of the substrate. The processor has a rotation driver configured to rotate the first holder around a vertical rotation axis. The substrate processing apparatus includes a charging member configured to charge a second substrate prepared separately from the substrate; and a controller configured to perform bringing the second substrate charged by the charging member into contact with the first holder.

### CROSS-REFERENCE TO RELATED APPLICATION

This application claims the benefit of Japanese Patent Application No. 2023-110014 filed on Jul. 4, 2023, the entire disclosure of which is incorporated herein by reference.

### TECHNICAL FIELD

The various aspects and embodiments described herein pertain generally to a substrate processing apparatus and a substrate processing method.

### BACKGROUND

A substrate processing apparatus described in Patent Document 1 includes two attraction pads, a liquid receiving cup, a spin chuck, a housing, a first cleaning device, and a second cleaning device. The two attraction pads attract and hold a bottom surface of a substrate horizontally. The liquid receiving cup is connected to the two attraction pads. The spin chuck horizontally attracts and holds the bottom surface of the substrate received from the attraction pad. The housing has an opening in a top surface thereof. A drain pipe for discharging a cleaning liquid and an exhaust pipe for exhausting an airflow are provided at a bottom of the housing. The first cleaning device cleans a top surface of the substrate. The second cleaning device cleans the bottom surface of the substrate.
Patent Document 1: Japanese Patent Laid-open Publication No. 2020-043156

### SUMMARY

In one exemplary embodiment, a substrate processing apparatus includes a processor configured to process a substrate with a processing liquid. The processor has a holder configured to hold the substrate horizontally. The holder includes a first holder configured to come into contact with a center of a bottom surface of the substrate. The processor has a rotation driver configured to rotate the first holder around a vertical rotation axis. The substrate processing apparatus includes a charging member configured to charge a second substrate prepared separately from the substrate; and a controller configured to perform bringing the second substrate charged by the charging member into contact with the first holder.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a substrate processing apparatus according to an exemplary embodiment;

FIG. 2 is a plan view illustrating an example of a processing device, showing an example of a process S104 in FIG. 8;

FIG. 3 is a cross sectional view illustrating an example of the process S104 of FIG. 8;

FIG. 4 is a plan view illustrating an example of a process S102 in FIG. 8;

FIG. 5 is a cross sectional view illustrating an example of the process S102 in FIG. 8;

FIG. 6 is a cross sectional view illustrating an example of an operation of an elevating pin;

FIG. 7 is a cross sectional view illustrating an example of an operation of the elevating pin following that of FIG. 6;

FIG. 8 is a flowchart illustrating an example of an operation of the processing device;

FIG. 9 is a flowchart illustrating an example of cleaning of the processing device;

FIG. 10 is a cross sectional view illustrating an example of a process S202 in FIG. 9;

FIG. 11 is a diagram illustrating an example of a distribution of an electrostatic force obtained in the process S202;

FIG. 12 is a cross sectional view illustrating an example of a process S203 in FIG. 9;

FIG. 13 is a cross sectional view illustrating an example of a process S204 in FIG. 9;

FIG. 14 is a cross sectional view illustrating an example of a process S206 in FIG. 9;

FIG. 15 is a diagram illustrating an example of a distribution of an electrostatic force obtained in the process S206;

FIG. 16 is a diagram illustrating an example of a distribution of an electrostatic force obtained in the process S206 when using a third substrate instead of a second substrate;

FIG. 17 is a diagram illustrating an example of the number of particles adhering to the substrate after cleaning the processing device with the second substrate or the third substrate;

FIG. 18 is a diagram illustrating an example of a third holder;

FIG. 19 is a plan view illustrating an example of a wall member; and

FIG. 20 is a cross sectional view illustrating an example of the wall member.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, same or corresponding parts will be assigned same reference numerals, and redundant descriptions thereof may be omitted. In the present specification, the X-axis direction, Y-axis direction, and Z-axis direction are directions perpendicular to each other. The X-axis direction and the Y-axis direction are horizontal directions, and the Z-axis direction is a vertical direction.

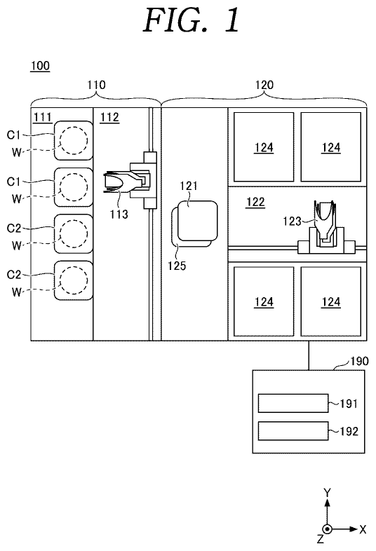

Referring to FIG. 1, a substrate processing apparatus 100 according to an exemplary embodiment will be described. The substrate processing apparatus 100 is configured to process a substrate W. The substrate W includes a semiconductor wafer such as, but not limited to, a silicon wafer. The substrate W may include a plurality of devices formed on the semiconductor wafer. The device includes, for example, an electronic circuit. The substrate W may be a stacked substrate prepared by stacking a plurality of semiconductor wafers on top of each other. The stacked substrate is obtained by bonding the plurality of semiconductor wafers.

The substrate processing apparatus 100 includes a carry-in/out station 110, a processing station 120, and a control device 190. The carry-in/out station 110 is provided with a placement table 111. Cassettes C1 and C2 are placed on the placement table 111. The cassette C1 accommodates the substrate W before being processed. The cassette C2 accommodates therein the substrate W after being processed. The number of the cassettes C1 and C2 is not particularly limited. A non-illustrated cassette may accommodate the substrate W when the substrate W has a problem during a processing.

The carry-in/out station 110 is provided with a first transfer area 112 and a first transfer device 113. The first transfer area 112 extends in the Y-axis direction, and is adjacent to the placement table 111 and a transition device 121. The first transfer device 113 is configured to transfer the substrate W between the plurality of devices adjacent to the first transfer area 112. The first transfer device 113 has a transfer arm configured to hold the substrate W, and a driver configured to move or rotate the transfer arm. The transfer arm is configured to be movable in horizontal directions (both in the X-axis direction and in the Y-axis direction) and a vertical direction, and rotatable around a vertical axis. A plurality of such transfer arms may be provided.

The processing station 120 is equipped with the transition device 121, a second transfer area 122, a second transfer device 123, a processing device 124, and a storage device 125. The second transfer device 123 is an example of a transferrer. Further, the processing device 124 is an example of a processor. Furthermore, the storage device 125 is an example of a storage. Here, the layout and the number of the devices constituting the processing station 120 are not limited to those shown in FIG. 1.

The transition device 121 temporarily stores the substrate W therein. The transition device 121 is provided between the first transfer area 112 and the second transfer area 122, and relays the substrate W between the first transfer device 113 and the second transfer device 123.

The second transfer area 122 extends in the X-axis direction, and is adjacent to the transition device 121, the processing device 124, and the storage device 125. The second transfer device 123 is configured to transfer the substrate W between the plurality of devices adjacent to the second transfer area 122. The second transfer device 123 has a transfer arm configured to hold the substrate W, and a driver configured to move or rotate the transfer arm. The transfer arm is configured to be movable in horizontal directions (both in the X-axis direction and in the Y-axis direction) and a vertical direction, and rotatable around a vertical axis. A plurality of such transfer arms may be provided.

The processing device 124 is configured to process the substrate W with a processing liquid. The processing liquid includes, for example, a chemical liquid and a rinse liquid. The chemical liquid is not particularly limited, and SC1 (a mixture of ammonia, hydrogen peroxide, and water) may be used as an example. The chemical liquid may be, besides a cleaning liquid that removes dirt on the substrate W, an etching liquid or a peeling liquid. The rinse liquid is, for example, DIW (deionized water). The chemical liquid and the rinse liquid may be supplied to the substrate W in this order.

The storage device 125 stores therein a second substrate W2 for use in cleaning of the processing device 124. The second substrate W2 is transferred from the storage device 125 to the processing device 124 by the second transfer device 123 to be used to clean the processing device 124. Thereafter, the second substrate W2 is returned from the processing device 124 back into the storage device 125 by the second transfer device 123. The used second substrate W2 is replaced with an unused second substrate W2 during maintenance of the substrate processing apparatus 100. Details regarding the second substrate W2 will be described later.

The control device 190 is, for example, a computer, and includes an operator 191 such as a CPU (Central Processing Unit) and a storage 192 such as a memory. The storage 192 stores therein a program for controlling various processings performed in the substrate processing apparatus 100. The control device 190 controls an operation of the substrate processing apparatus 100 by causing the operator 191 to execute the program stored in the storage 192. A device controller configured to control an operation of each device constituting the substrate processing apparatus 100 may be provided, and a system controller that controls the device controllers in overall may be provided. The control device 190 may be composed of the device controllers and the system controller. The control device 190 is an example of a controller.

Now, an example of the operation of the substrate processing apparatus 100 will be described. First, the first transfer device 113 takes out the substrate W from the cassette C1 and transfers it to the transition device 121. Then, the second transfer device 123 takes out the substrate W from the transition device 121 and transfers it to the processing device 124.

Subsequently, the processing device 124 processes the substrate W with the processing liquid. Thereafter, the second transfer device 123 takes out the substrate W from the processing device 124 and transfers it to the transition device 121. Finally, the first transfer device 113 takes out the substrate W from the transition device 121 and stores it in the cassette C2.

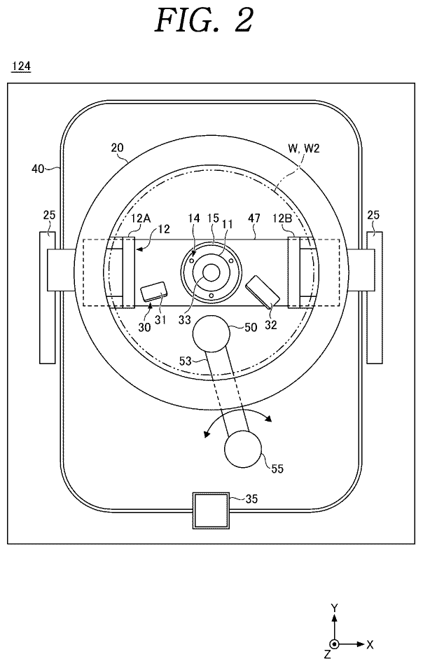

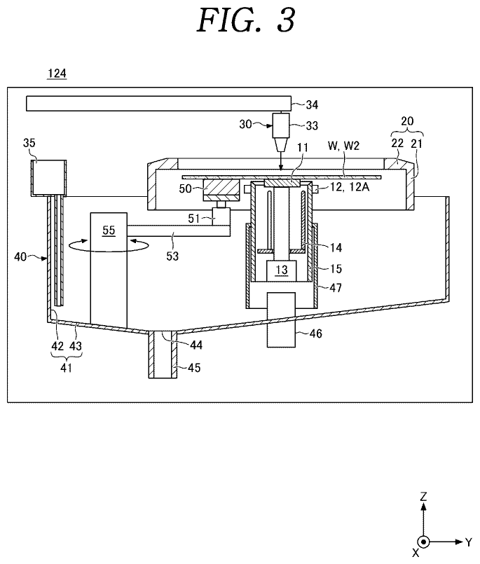

Referring to FIG. 2 to FIG. 7, an example of the processing device 124 will be explained. As mainly illustrated in FIG. 3, the processing device 124 includes, by way of example, a first holder 11, a second holder 12, a rotation driver 13, a cup 20, a movement driver 25 (see FIG. 2), a processing liquid supply 30, a processing tub 40, a drain pipe 45, an exhaust pipe 46, an exhaust pipe cover 47, a friction body 50, and a friction body mover 55.

The first holder 11 comes into contact with a center of the bottom surface of the substrate W and holds the substrate W horizontally. At this time, the first holder 11 is in contact with only a portion of the bottom surface of the substrate W. The first holder 11 vacuum-attracts the substrate W in the present exemplary embodiment, but it may be configured to electrostatically attract the substrate W. The first holder 11 is, for example, a spin chuck, and is rotated by the rotation driver 13. The first holder 11 is rotated around a vertical rotation axis. The first holder 11 may be movable in the Z-axis direction.

A plurality of elevating pins 14 is disposed around the first holder 11. The plurality of elevating pins 14 are configured to lower or raise the substrate W with respect to the first holder 11 or the second holder 12. The plurality of elevating pins 14 are arranged at a equal distance therebetween in a circumferential direction of the first holder 11. The plurality of elevating pins 14 are moved up and down around the first holder 11, thereby delivering the substrate W between the first holder 11 or the second holder 12 and a non-illustrated transfer arm.

Further, a gas discharge ring 15 is disposed around the first holder 11. The gas discharge ring 15 surrounds the first holder 11, and forms a ring-shaped gas curtain toward the bottom surface of the substrate W. The gas curtain protects the first holder 11 by restricting the processing liquid from reaching an inside from an outside thereof. The gas curtain also protects the plurality of elevating pins 14 disposed inside the gas curtain. The gas discharge ring 15 is an example of a gas discharger. The gas discharger does not need to be of the ring-shape.

The second holder 12 comes into contact with the bottom surface of the substrate W on a diametrically outer side of the substrate W than the first holder 11, and holds the substrate W horizontally. At this time, the second holder 12 is in contact with only a portion of the bottom surface of the substrate W. The second holder 12 vacuum-attracts the substrate W in the present exemplary embodiment, but it may be configured to electrostatically attract the substrate W. The second holder 12 includes a pair of attraction pads 12A and 12B arranged at a distance therebetween in the X-axis direction. The pair of attraction pads 12A, 12B are arranged with the first holder 11 therebetween in the X-axis direction. The second holder 12 is connected to the cup 20, and is movable in a horizontal direction (Y-axis direction) and a vertical direction together with the cup 20.

The cup 20 has a ring shape with open top and bottom, and surrounds a periphery of the substrate W held by the first holder 11 or the second holder 12. The cup 20 has a cylindrical vertical wall 21, and an upper wall 22 protruding diametrically inwards from an upper end of the cylindrical vertical wall 21. The cup 20 receives the processing liquid supplied to the substrate W.

The movement driver 25 moves the second holder 12 in a horizontal direction (Y-axis direction) perpendicular to the rotation axis of the first holder 11 and a vertical direction (Z-axis direction). The movement driver 25 moves the second holder 12 together with the cup 20. The cup 20 is moved inside the processing tub 40. When viewed from above, a side surface 42 of the processing tub 40 surrounds the entire movement range of the cup 20.

The processing liquid supply 30 supplies the processing liquid to the substrate W surrounded by the cup 20. The processing liquid includes, for example, a chemical liquid and a rinse liquid. The chemical liquid is not particularly limited. By way of example, the chemical liquid may be SC1 (a mixture of ammonia, hydrogen peroxide, and water). The chemical liquid may be, besides a cleaning liquid for removing dirt on the substrate W, an etching liquid or a peeling liquid. The rinse liquid is, for example, DIW (deionized water). The chemical liquid and the rinse liquid may be supplied to the substrate W in this order.

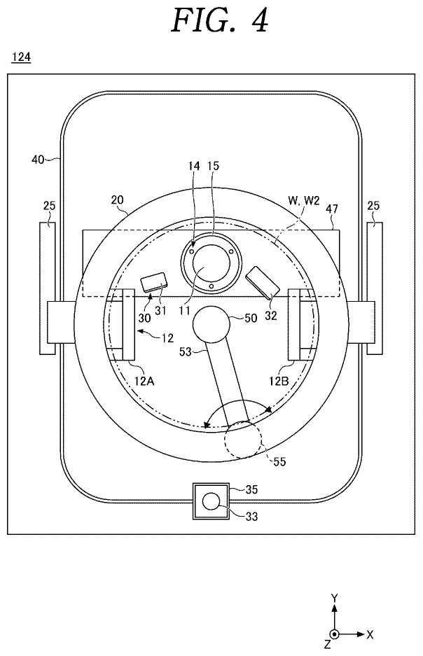

The processing liquid supply 30 has lower nozzles 31 and 32 (see FIG. 2 and FIG. 4) configured to supply the processing liquid to the bottom surface of the substrate W. Each of the lower nozzles 31 and 32 is connected to a source of the processing liquid via a non-illustrated pipeline. The pipeline is provided with a valve and a flow rate controller. When the valve opens a flow path of the pipeline, the processing liquid is discharged from the lower nozzles 31 and 32. A discharge amount is controlled by the flow rate controller. Meanwhile, when the valve closes the flow path of the pipeline, the discharge of the processing liquid is stopped.

The processing liquid supply 30 has an upper nozzle 33 (see FIG. 3) configured to supply the processing liquid to the top surface of the substrate W. The upper nozzle 33, like the lower nozzles 31 and 32, is connected to a source of the processing liquid via a non-illustrated pipeline. The upper nozzle 33 may be a two-fluid nozzle, and may be configured to break and atomize the processing liquid with a gas such as N₂ gas before discharging it.

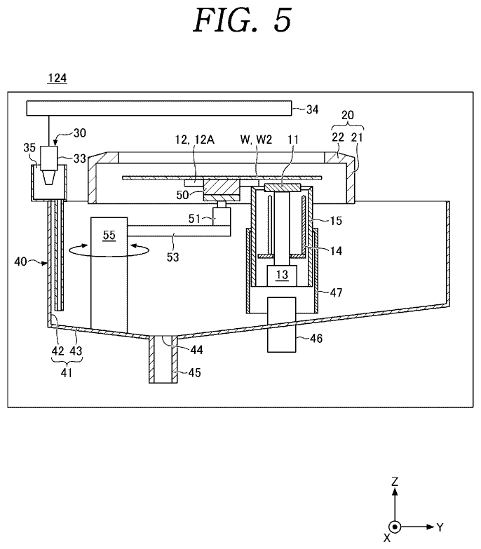

The processing liquid supply 30 has a nozzle mover 34 configured to move the upper nozzle 33 in a horizontal direction and a vertical direction. The nozzle mover 34 moves the upper nozzle 33 between a position (see FIG. 3) where the upper nozzle 33 supplies the processing liquid to the substrate W surrounded by the cup 20 and a position (see FIG. 5) where a discharge port of the upper nozzle 33 is accommodated in a nozzle bath 35.

The nozzle bath 35 is also called a dummy dispense port. Immediately before the processing liquid is discharged from the upper nozzle 33 to the substrate W, an old processing liquid (for example, the processing liquid whose temperature has decreased) collected in the upper nozzle 33 is discharged into the nozzle bath 35, so a new processing liquid (for example, the processing liquid whose temperature is controlled to a required temperature) can be supplied to the substrate W. A discharge pipe is provided in a bottom wall of the nozzle bath 35. The discharge pipe discharges the processing liquid collected inside the nozzle bath 35 into the processing tub 40. The discharge pipe is vertically provided. The processing liquid flows and falls down inside the discharge pipe by gravity. A lower end of the discharge pipe is disposed above a bottom surface 43 of the processing tub 40.

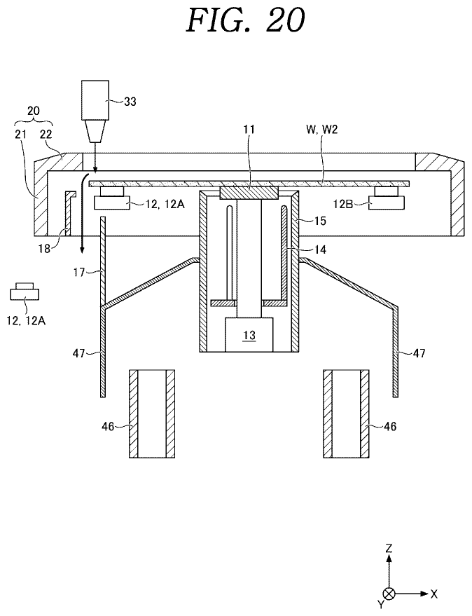

The processing tub 40 collects the processing liquid that falls from the cup 20. The processing tub 40 has, for example, a box shape with an open top. An inner wall surface 41 of the processing tub 40 has the side surface 42 and the bottom surface 43. The bottom surface 43 has an outlet 44 through which the processing liquid is discharged. A drain pipe 45 is provided at the outlet 44. The drain pipe 45 discharges the processing liquid from an inside of the processing tub 40 to an outside thereof. In addition to the drain pipe 45, exhaust pipes 46 are also provided in the bottom surface 43 of the processing tub 40. For example, the exhaust pipes 46 are provided on both sides in the X-axis direction with the rotation driver 13 therebetween (see FIG. 20).

The exhaust pipes 46 exhaust a gas from the inside of the processing tub 40 to the outside thereof. The exhaust pipes 46 are protruded upwards from the bottom surface 43 of the processing tub 40. The exhaust pipes 46 are covered with an exhaust pipe cover 47 from above. The exhaust pipe cover 47 suppresses droplets of the processing liquid from entering the exhaust pipe 46. Further, the exhaust pipe cover 47 protects the rotation driver 13 from the droplets of the processing liquid. The exhaust pipe cover 47 extends in both the positive X-axis direction and the negative X-axis direction with respect to the rotation driver 13.

The friction body 50 rubs the bottom surface of the substrate W. The friction body 50 is a brush or a sponge. The friction body 50 has, for example, a cylindrical shape, and a top surface of the friction body 50 is placed horizontally. The top surface of the friction body 50 is smaller than the bottom surface of the substrate W. The friction body 50 is formed of a resin such as, but not limited to, PVA (polyvinyl alcohol).

The friction body 50 is rotated by a rotation motor 51. The rotation motor 51 is provided at one end of an arm 53. A friction body mover 55 is provided at the other end of the arm 53. The friction body mover 55 moves the friction body 50 in a horizontal direction and a vertical direction via the arm 53.

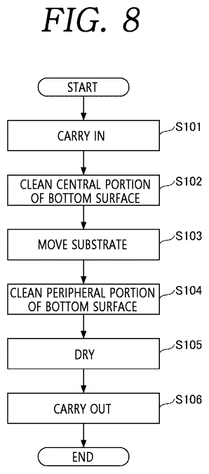

Now, referring to FIG. 8, an example of an operation of the processing device 124 will be described. As shown in FIG. 8, the processing device 124 performs processes S101 to S106. The processes S101 to S106 are performed under control of the controller 90.

The process S101 includes carrying the substrate W into the processing device 124 from an outside thereof. First, the transfer arm of the second transfer device 123 transfers the substrate W to above the cup 20, and stands by above the cup 20. At this time, when viewed from above, a center of the substrate W, a center of the first holder 11, and a center of the cup 20 overlap, as shown in FIG. 2.

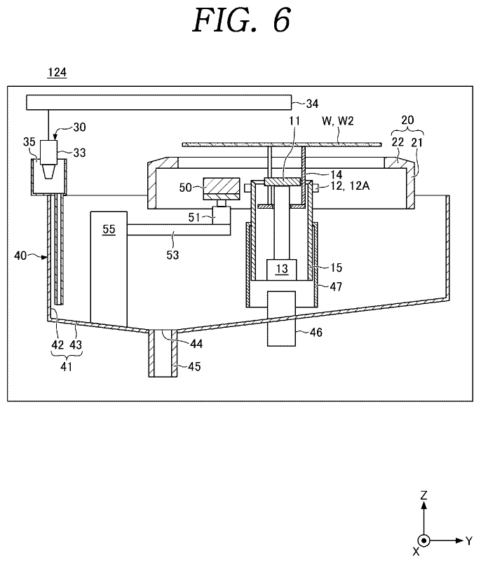

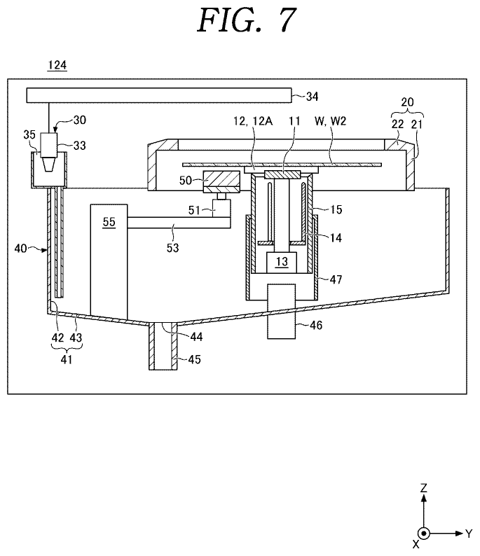

Next, the plurality of elevating pins 14 are raised, and the plurality of elevating pins 14 lift up the substrate W from the transfer arm of the second transfer device 123 (see FIG. 6). Here, instead of the elevating pins 14 being raised, the transfer arm may be lowered. Next, when the transfer arm is withdrawn from the processing device 124, the cup 20 is raised and the plurality of elevating pins 14 are lowered, so that the substrate W is handed over to the second holder 12 from the plurality of elevating pins 14 (see FIG. 7). Subsequently, the second holder 12 attracts a peripheral portion of the bottom surface of the substrate W. Afterwards, as shown in FIG. 4, the movement driver 25 moves the second holder 12 together with the cup 20 horizontally to a position where the friction body 50 overlaps a central portion of the bottom surface of the substrate W, when viewed from above.

The process S102 includes cleaning the central portion of the bottom surface of the substrate W while the peripheral portion of the bottom surface of the substrate W is attracted by the second holder 12 (see FIG. 5). The lower nozzles 31 and 32 supply the processing liquid to the bottom surface of the substrate W, and the friction body mover 55 moves the friction body 50 horizontally while pressing it against the central portion of the bottom surface of the substrate W. Further, the movement driver 25 moves the second holder 12 horizontally together with the cup 20. Here, a moving direction of the friction body 50 is a direction that intersects a moving direction of the cup 20.

The process S103 includes moving the substrate W from the second holder 12 to the first holder 11. First, as shown in FIG. 2, the movement driver 25 horizontally moves the second holder 12 together with the cup 20 to a position where the center of the substrate W and the center of the first holder 11 overlap, when viewed from above. Thereafter, the movement driver 25 lowers the cup 20, so that the substrate W is handed over to the first holder 11 from the second holder 12. The second holder 12 releases the attraction of the peripheral portion of the bottom surface of the substrate W, and the first holder 11 attracts the central portion of the bottom surface of the substrate W.

The process S104 includes cleaning the peripheral portion of the bottom surface of the substrate W while the central portion of the bottom surface of the substrate W is attracted by the first holder 11 (see FIG. 3). The lower nozzles 31 and 32 supply the processing liquid to the bottom surface of the substrate W, and the friction body mover 55 moves the friction body 50 horizontally while pressing it against the peripheral portion of the bottom surface of the substrate W. Also, the rotation driver 13 rotates the substrate W together with the first holder 11.

Further, while the rotation driver 13 is rotating the substrate W together with the first holder 11, cleaning of the top surface of the substrate W is performed. For example, the upper nozzle 33 supplies the processing liquid to the top surface of the substrate W. The upper nozzle 33 may supply the processing liquid to a central portion of the top surface of the substrate W, or may be moved in a diametrical direction of the substrate W to supply the processing liquid to the entire top surface of the substrate W in the diametrical direction. Further, a non-illustrated second friction body may be configured to rub the top surface of the substrate W. In addition, a non-illustrated third friction body may be configured to rub a bevel of the substrate W.

The process S105 includes drying the substrate W. For example, the rotation driver 13 rotates the first holder 11 at a high speed to shake off the processing liquid adhering to the substrate W.

The process S106 includes carrying out the substrate W from the inside of the processing device 124 to the outside thereof. First, the first holder 11 releases the attraction of the substrate W, and the plurality of elevating pins 14 are raised to lift up the substrate W from the first holder 11. Next, the transfer arm of the second transfer device 123 is advanced into the processing device 124 from the outside thereof, and stands by above the cup 20. Subsequently, the plurality of elevating pins 14 are lowered, so that the substrate W is handed over to the transfer arm from the plurality of elevating pins 14. Here, instead of the elevating pins 14 being lowered, the transfer arm may be raised. Afterwards, the transfer arm is taken out from the processing device 124 while holding the substrate W thereon.

Here, however, when the first holder 11 holds the substrate W, dirt on the substrate W may be transferred to the first holder 11 to contaminate the first holder 11. If the first holder 11 holds another substrate W afterwards, the other substrate W is also contaminated. Conventionally, in order to remove the dirt from the first holder 11, a worker would periodically wipe the dirt off the first holder 11 with a fibrous wipe such as a rag, or prepare a multiple number of clean substrates W and bring the substrates W into contact with the first holder 11 in sequence.

In the present exemplary embodiment, a second substrate W2 is prepared separately from the substrate W, the second substrate W2 is electrically charged, and the charged second substrate W2 is brought into contact with the first holder 11, as will be described in detail later. At this time, the second substrate W2 needs to have opposite polarity to that of particles adhering to the first holder 11. The particles can be attached to the second substrate W2 by an electrostatic force, and thus can be removed from the first holder 11 together with the second substrate W2. Accordingly, the first holder 11 can be efficiently cleaned.

Additionally, as will be described later, the content of the present disclosure is also applicable to cleaning the elevating pins 14. Specifically, the second substrate W2 is electrically charged, and the elevating pins 14 are brought into contact with the charged second substrate W2. At this time, the second substrate W2 needs to have opposite polarity to that of particles adhering to the elevating pins 14. The particles can be attached to the second substrate W2 by an electrostatic force, and thus can be removed from the elevating pins 14 together with the second substrate W2. Accordingly, the elevating pins 14 can be cleaned efficiently.

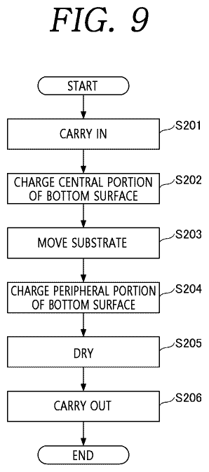

Now, with FIG. 9 to FIG. 17, an example of cleaning of the processing device 124 will be explained. As illustrated in FIG. 9, the processing device 124 performs processes S201 to S206. The processes S201 to S206 are performed regularly under the control of the controller 90. In the processes S201 to S206, the prepared second substrate W2 is used instead of the substrate W.

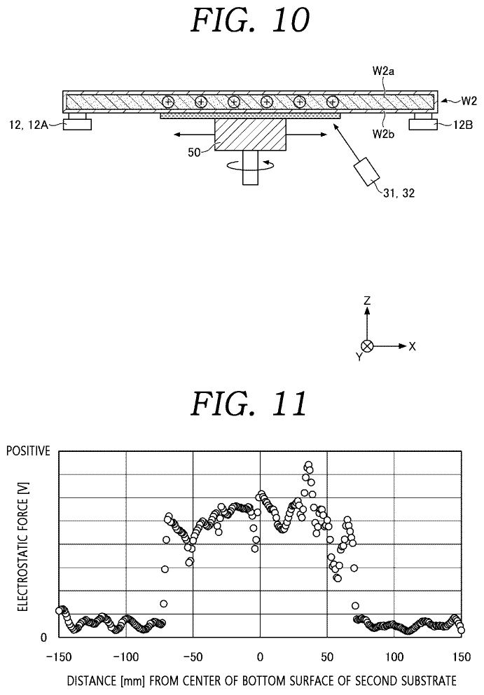

As shown in FIG. 10, the second substrate W2 has, for example, a support substrate W2a and an oxide film W2b. The support substrate W2a is a silicon wafer in the present exemplary embodiment. However, the support substrate W2 is not particularly limited, and may be, by way of another example, a compound semiconductor wafer or a glass substrate. The oxide film W2b is a silicon oxide film in the present exemplary embodiment, but the oxide film W2b is not particularly limited and may contain, for example, at least one of nitrogen and carbon in addition to oxygen.

The oxide film W2b can be positively charged by being rubbed with the friction body 50. Meanwhile, particles are known to be negatively charged in the presence of an alkaline aqueous solution. That is, the oxide film W2b can be charged with a polarity opposite to that of the particles. The oxide film W2b is formed by a thermal oxidation method in the present exemplary embodiment. Alternatively, the oxide film W2b may be formed by a CVD (Chemical Vapor Deposition) method, an ALD (Atomic Layer Deposition) method, or the like.

The second substrate W2 desirably has an oxide film W2b on at least a bottom surface thereof. This is because the processing device 124 tends to easily collect particles below the second substrate W2. If the second substrate W2 has the oxide film W2b on its bottom surface, the particles existing below the second substrate W2 can be attracted to the second substrate W2. Additionally, the second substrate W2 of the present exemplary embodiment has the oxide film W2b on its entire surface.

The process S201 includes carrying the second substrate W2 into the processing device 124 from an outside thereof. First, the transfer arm of the second transfer device 123 transfers the second substrate W2 to above the cup 20, and stands by above the cup 20. At this time, when viewed from above, a center of the second substrate W2, the center of the first holder 11, and the center of the cup 20 overlap, as illustrated in FIG. 2.

Subsequently, the plurality of elevating pins 14 are raised, and the plurality of elevating pins 14 lift up the second substrate W2 from the transfer arm of the second transfer device 123 (see FIG. 6). Here, instead of the elevating pins 14 being raised, the transfer arm may be lowered. Then, the transfer arm is withdrawn from the processing device 124, and the cup 20 is raised and the plurality of elevating pins 14 are lowered, so that the second substrate W2 is handed over to the second holder 12 from the plurality of elevating pins 14 (see FIG. 7). Thereafter, the second holder 12 attracts a peripheral portion of the bottom surface of the second substrate W2. Afterwards, as shown in FIG. 4, the movement driver 25 moves the second holder 12 horizontally together with the cup 20 to a position where the friction body 50 overlaps the central portion of the bottom surface of the second substrate W2, when viewed from above.

The process S202 includes charging the central portion of the bottom surface of the second substrate W2 while the peripheral portion of the bottom surface of the second substrate W2 is attracted by the second holder 12 (see FIG. 10). The friction body mover 55 moves the friction body 50 horizontally while pressing it against the central portion of the bottom surface of the second substrate W2. Also, the movement driver 25 horizontally moves the second holder 12 together with the cup 20. Here, a moving direction of the friction body 50 is a direction that intersects a moving direction of the cup 20.

The friction body 50 rubs the central portion of the bottom surface of the second substrate W2 to charge it. The friction body 50 is an example of a charging member. The central portion of the bottom surface of the second substrate W2 and the friction body 50 are charged to have opposite polarities. For example, when the bottom surface of the second substrate W2 is composed of the oxide film W2b and the friction body 50 is composed of the resin such as PVA, the central portion of the bottom surface of the second substrate W2 is positively charged, and the friction body 50 is negatively charged.

The lower nozzles 31 and 32 supply an alkaline aqueous solution between the friction body 50 and the second substrate W2 held by the second holder 12. Although the alkaline aqueous solution is not particularly limited, it may be, by way of example, diluted ammonia water. As compared to pure water, the alkaline aqueous solution can accelerate friction charging of the second substrate W2 and increase the amount of electric charges in the second substrate W2. Further, the alkaline aqueous solution can charge particles negatively. Therefore, a large number of particles can be attached to the second substrate W2 by an electrostatic force.

It is desirable that the lower nozzles 31 and 32 continuously supply the alkaline aqueous solution to the central portion of the bottom surface of the second substrate W2 from before starting the rubbing of the second substrate W2 with the friction body 50 until after the completion of the rubbing of the second substrate W2 with the friction boy 50 in order to suppress scratches due to friction. After the lower nozzles 31 and 32 start the supply of the alkaline aqueous solution, the friction body 50 begins to rub the second substrate W2. Further, after the friction body 50 has completely rubbed the second substrate W2, the lower nozzles 31 and 32 stop the supply of the alkaline aqueous solution.

FIG. 11 shows an example of a distribution of the electrostatic force obtained in the process S202. The present inventor has prepared a second substrate in which a thermal oxide film is formed on the entire surface of a silicon wafer, has rubbed a central portion of a bottom surface of the second substrate with a brush made of PVA, and has observed that the central portion of the bottom surface of the second substrate is positively charged, as shown in FIG. 11. Furthermore, although not shown, it is also observed that the larger the thickness of the thermal oxide film, the larger the capacitance of the thermal oxide film and the larger the amount of electric charges in the second substrate.

The process S203 includes moving the second substrate W2 from the second holder 12 to the first holder 11. First, as shown in FIG. 2, the cup 20 is moved horizontally to a position where the center of the second substrate W2 and the center of the first holder 11 overlap, when viewed from above. In the meantime, the gas discharge ring 15 discharges a gas to the bottom surface of the second substrate W2, thereby allowing the bottom surface of the second substrate W2 to be dried.

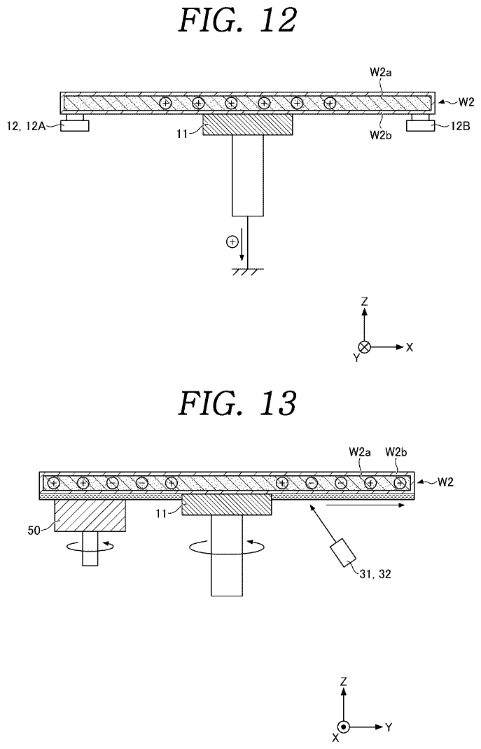

Thereafter, the movement driver 25 lowers the cup 20, so that the second substrate W2 is handed over to the first holder 11 from the second holder 12. The second holder 12 releases the attraction of the peripheral portion of the bottom surface of the second substrate W2, and the first holder 11 attracts the central portion of the bottom surface of the second substrate W2. As a result, as depicted in FIG. 12, the central portion of the bottom surface of the second substrate W2 comes into contact with the first holder 11.

At this time, the particles adhering to the first holder 11 and the central portion of the bottom surface of the second substrate W2 have opposite polarities. Therefore, the particles can be attached to the second substrate W2 by an electrostatic force, so the particles can be removed from the first holder 11 together with the second substrate W2. Accordingly, the first holder 11 can be cleaned efficiently.

Further, as the second substrate W2 and the first holder 11 come into contact with each other, the positive charges accumulated in the central portion of the bottom surface of the second substrate W2 flow out to the first holder 11. As a result, the amount of the electric charges in the central portion of the bottom surface of the second substrate W2 decreases.

The process S204 includes charging the peripheral portion of the bottom surface of the second substrate W2 while the central portion of the bottom surface of the second substrate W2 is attracted by the first holder 11 (see FIG. 13). The friction body mover 55 moves the friction body 50 horizontally while pressing it against the peripheral portion of the bottom surface of the second substrate W2. Also, the rotation driver 13 rotates the second substrate W2 together with the first holder 11. The friction body 50 rubs the peripheral portion of the bottom surface of the second substrate W2 to charge it.

In the process S204, flow charging is dominant over friction charging. Flow charging is a phenomenon that an electrostatic force distribution occurs when a liquid flows in a solid surface. In the process S204, as the rotation driver 13 rotates the second substrate W2, the alkaline aqueous solution flows from a diametrically inner side of the second substrate W2 toward a diametrically outer side thereof due to a centrifugal force. In that process, flow charging occurs, as will be described later. Further, in the process S202, since the rotation driver 13 does not rotate the second substrate W2, flow charging hardly occurs.

The lower nozzles 31 and 32 supply the alkaline aqueous solution between the friction body 50 and the second substrate W2 held by the second holder 12. The alkaline aqueous solution is supplied to a portion between the central portion and the peripheral portion of the bottom surface of the second substrate W2, and is made to flow to the peripheral portion of the bottom surface of the second substrate W2 by a centrifugal force. The alkaline aqueous solution contains negative ions and positive ions. At a position where the alkaline aqueous solution is supplied, the negative ions are likely to be attracted to the second substrate W2. The remaining positive ions are attracted to the peripheral portion of the bottom surface of the second substrate W2. As a result, an electrostatic force distribution shown in FIG. 13 occurs.

The process S205 includes drying the second substrate W2. For example, the rotation driver 13 rotates the first holder 11 at a high speed to shake off the processing liquid adhering to the second substrate W2.

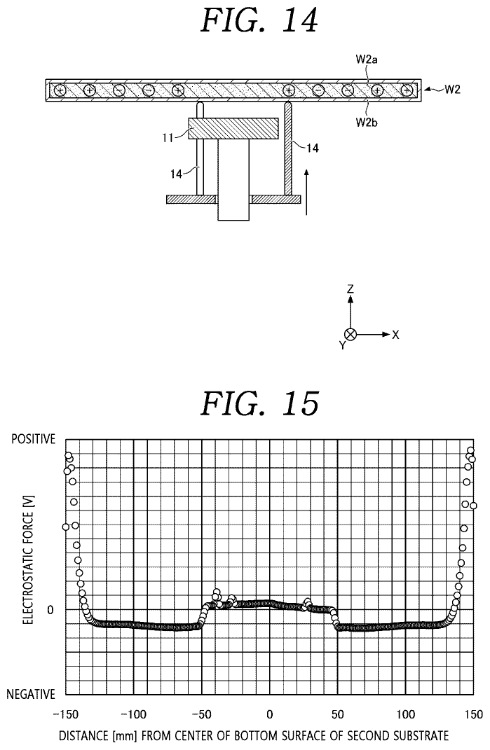

The process S206 includes carrying out the second substrate W2 from the inside of the processing device 124 to the outside thereof. First, the first holder 11 releases the attraction of the second substrate W2, and the plurality of elevating pins 14 are raised to lift up the second substrate W2 from the first holder 11. As a result, as shown in FIG. 14, the plurality of elevating pins 14 come into contact with the central portion of the bottom surface of the second substrate W2.

At this time, particles adhering to the plurality of elevating pins 14 and the central portion of the bottom surface of the second substrate W2 have opposite polarities. Therefore, the particles can be attached to the second substrate W2 by an electrostatic force, and thus can be removed from the elevating pins 14 together with the second substrate W2. Accordingly, the plurality of elevating pins 14 can be cleaned efficiently.

The transfer arm of the second transfer device 123 is advanced into the processing device 124 from the outside thereof, and stands by above the cup 20. Subsequently, the plurality of elevating pins 14 are lowered, and the second substrate W2 is handed over to the transfer arm from the plurality of elevating pins 14. Here, instead of the elevating pins 14 being lowered, the transfer arm may be raised. Thereafter, the transfer arm is taken out from the processing device 124 while holding the second substrate W2 thereon.

At this time, the transfer arm comes into contact with the peripheral portion of the bottom surface of the second substrate W2. Particles adhering to the transfer arm of the second transfer device 123 and the peripheral portion of the bottom surface of the second substrate W2 have opposite polarities. Therefore, the particles can be attached to the second substrate W2 by an electrostatic force, and thus can be removed from the transfer arm together with the second substrate W2. Accordingly, the transfer arm can be cleaned efficiently.

FIG. 15 shows an example of the electrostatic force distribution obtained in the process S206. The present inventor has prepared a silicon wafer having a thermal oxide film on the entire surface thereof as the second substrate W2, and has performed the processes S202 to S206 to confirm that the peripheral portion of the bottom surface of the second substrate W2 is positively charged, as shown in FIG. 15. Further, although not shown, it has also been confirmed that the larger the thickness of the thermal oxide film, the larger the electrostatic capacity of the thermal oxide film and the larger the amount of electric charges in the second substrate W2 upon the completion of the process S206.

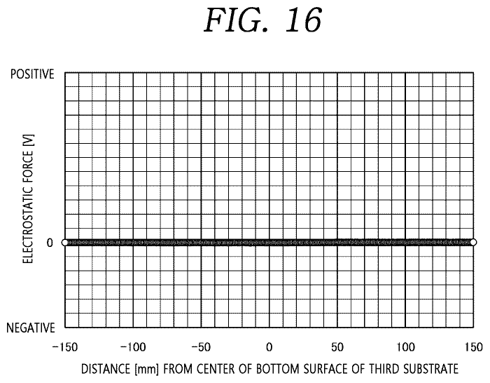

FIG. 16 shows an example of an electrostatic force distribution obtained in the process S206 when a third substrate is used instead of the second substrate W2. The third substrate has only a silicon wafer without having a thermal oxide film on a surface thereof. As shown in FIG. 16, the amount of electric charges is found to be small in an entire diametrical direction of the third substrate. As can be seen from the comparison of FIG. 15 and FIG. 16, the thermal oxide film contributes to charging.

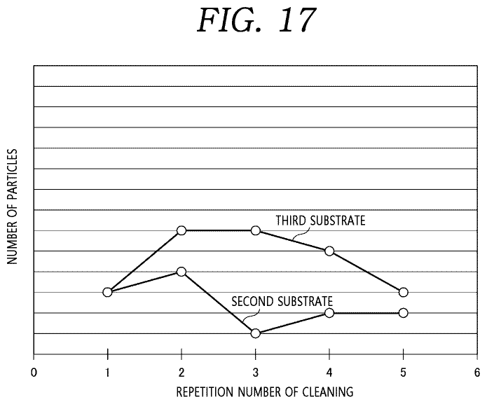

Referring to FIG. 17, an example of the number of particles attached to the substrate W after the processing device 124 is cleaned with the second substrate W2 or the third substrate will be described. In FIG. 17, the substrate W to which 60,000 Si particles have been attached is processed in the processing device 124 in advance, thereby contaminating the processing device 124. Then, cleaning the processing device 124 with the second substrate W2 or the third substrate is repeated, and after the n^{th} cleaning and before the (n+1)^{th} cleaning, the number of particles is measured.

As shown in FIG. 17, when the processing device 124 is cleaned with the second substrate W2, the number of particles attached to the substrate W can be reduced as compared to the case where the processing device 124 is cleaned with the third substrate. The second substrate W2, unlike the third substrate, has a thermal oxide film. Therefore, it is assumed that the second substrate W2 is easier to charge than the third substrate and is thus likely to easily attract particles by an electrostatic force, so that the processing device 124 can be cleaned efficiently.

In the present exemplary embodiment, the second substrate W2 is stored in the storage device 125. However, the second substrate W2 may be accommodated in a cassette placed on the placement table 111. In the latter case, the first transfer device 113 takes out the second substrate W2 from the cassette and transfers it to the transition device 121. Subsequently, the second transfer device 123 takes out the second substrate W2 from the transition device 121 and transfers it to the processing device 124. Afterwards, the second substrate W2 is returned back into the cassette in the reverse order. In this case, not only the transfer arm of the second transfer device 123 but also the transfer arm of the first transfer device 113 can be cleaned with the second substrate W2.

When the second substrate W2 is stored in the storage device 125, the storage device 125 may have a non-illustrated charging member. The charging member may charge the second substrate W2 by rubbing it, or may charge the second substrate W2 by radiating ions to the second substrate W2. The second transfer device 123 may bring the second substrate W2 charged in the storage device 125 into contact with the plurality of elevating pins 14 and the second holder 12 in sequence in the process S201. The content of the present disclosure is also applicable to cleaning the elevating pins 14 and cleaning the second holder 12.

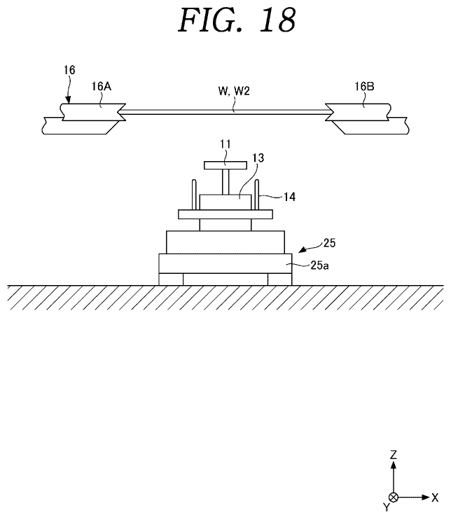

Instead of the second holder 12, the processing device 124 may have a third holder 16 as shown in FIG. 18. The third holder 16 holds a periphery of the substrate W. The third holder 16 can hold the second substrate W2 instead of the substrate W. The third holder 16 is disposed above the first holder 11. The third holder 16 has a pair of movable claws 16A and 16B configured to hold the substrate W therebetween. The pair of movable claws 16A and 16B are provided at a distance therebetween in the X-axis direction, and are configured to approach or distance away from each other. Further, instead of the movable claws 16A and 16B, a rotating top may be used. Three or more rotating tops may be provided at a distance therebetween along the circumferential direction of the substrate W.

The plurality of elevating pins 14 are moved up and down around the first holder 11 to deliver the substrate W between the first holder 11 or the third holder 16 and the transfer arm of the second transfer device 123. The plurality of elevating pins 14 are mounted on a Y-axis slider 25a and are moved in the Y-axis direction together with the first holder 11. Alternatively, the plurality of elevating pins 14 may not be mounted on the Y-axis slider 25a but may be arranged at a distance therebetween in the Y-axis direction.

The substrate W is handed over to the elevating pins 14 from the transfer arm of the second transfer device 123, and then passed from the elevating pins 14 to the third holder 16. With the periphery of the substrate W held by the third holder 16, a non-illustrated friction body cleans the central portion of the bottom surface of the substrate W. Thereafter, the substrate W is handed over from the third holder 16 to the elevating pins 14, and then handed over from the elevating pins 14 to the first holder 11. With the central portion of the bottom surface of the substrate W held by the first holder 11, a non-illustrated friction body cleans the peripheral portion of the bottom surface of the substrate W. At this time, the substrate W is rotated along with the first holder 11.

In this modification example, cleaning of the first holder 11, cleaning of the third holder 16, or cleaning of the elevating pins 14 can be performed by using the second substrate W2, the same as in the above-described exemplary embodiment.

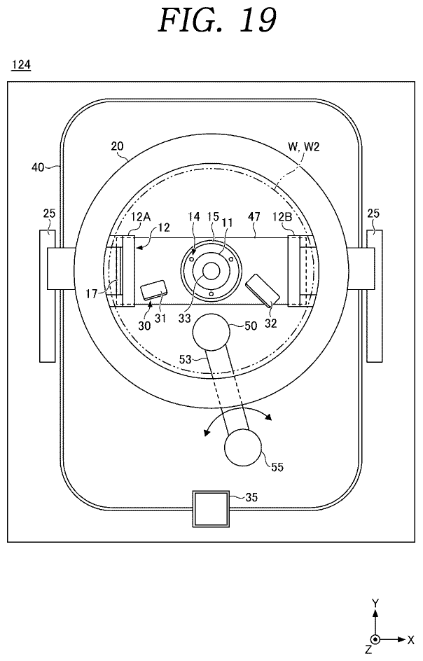

Now, with reference to FIG. 19 and FIG. 20, an example of a wall member will be described. The processing device 124 may have a wall member 17, as shown in FIG. 19 and FIG. 20. As illustrated in FIG. 20, the wall member 17 is provided below the substrate W held by the first holder 11, and serves to block the processing liquid discharged by the upper nozzle 33 toward the periphery of the substrate W from heading toward the first holder 11. A residue of the processing liquid can be suppressed from adhering to the first holder 11 or the bottom surface of the substrate W, so that particle generation can be suppressed. This is especially effective when the upper nozzle 33 is a two-fluid nozzle. The two-fluid nozzle breaks and atomizes the processing liquid with a gas such as a N₂ gas before discharging it.

As illustrated in FIG. 19, the wall member 17 is provided at an inner side than the periphery of the substrate W held by the first holder 11 and an outer side than the gas discharge ring 15 in the diametrical direction of the substrate W. The gas discharge ring 15 is provided at an inner side than the lower nozzles 31 and 32 and an outer side than the first holder 11 in the diametrical direction of the substrate W. As shown in FIG. 19, the wall member 17 is provided at an inner side than the periphery of the substrate W in the diametrical direction of the substrate W and an outer side than the gas discharge ring 15 in the diametrical direction of the substrate W. With this configuration, the processing liquid discharged by the upper nozzle 33 toward the periphery of the substrate W can be blocked from heading toward the first holder 11.

As depicted in FIG. 19, when viewed from above, the entire wall member 17 is disposed at an inner side than the periphery of the substrate W held by the first holder 11 in the diametrical direction of the substrate W. The wall member 17 only needs to be provided in the vicinity of the upper nozzle 33, as shown in FIG. 20. The wall member 17 may be provided in a ring shape along the periphery of the substrate W held by the first holder 11. The wall member 17 has a flat plate shape in the present exemplary embodiment, but it may also have a curved plate shape. The wall member 17 is configured to project upwards from a top surface of the exhaust pipe cover 47.

The top surface of the exhaust pipe cover 47 is desirably disposed so as not to bounce back the processing liquid that is discharged by the upper nozzle 33 toward the periphery of the substrate W. Desirably, when viewed from above, the entire exhaust pipe cover 47 is disposed at an inner side than the periphery of the substrate W held by the first holder 11 in the diametrical direction of the substrate W.

The processing device 124 may have a second wall member 18, as illustrated in FIG. 20. The second wall member 18, like the wall member 17, is provided below the substrate W held by the first holder 11, but is provided at an outer side than the wall member 17 in the diametrical direction of the substrate W. The second wall member 18 is provided at an outer side than the periphery of the substrate W held by the first holder 11 in the diametrical direction of the substrate W and an inner side than the cup 20 in the diametrical direction of the substrate W.

At the inner side than the cup 20 in the diametrical direction of the substrate W, the second wall member 18 serves to guide downwards the processing liquid discharged by the upper nozzle 33 toward the periphery of the substrate W. By narrowing the passage of the processing liquid, the downward flow can be strengthened. Therefore, generation of an upward flow can be suppressed, and particles can be suppressed from floating.

As shown in FIG. 20, the second wall member 18 only needs to be provided near the upper nozzle 33. The second wall member 18 may be provided in a ring shape along the periphery of the substrate W held by the first holder 11. The second wall member 18 has a flat plate shape in the present exemplary embodiment, but it may also have a curved plate shape.

It is desirable to increase a discharge flow rate of the processing liquid discharged from the lower nozzles 31 and 32 while the upper nozzle 33 is discharging the processing liquid toward the periphery of the substrate W, as compared to a discharge flow rate of the processing liquid while the friction body 50 is rubbing the central portion of the bottom surface of the substrate W. As the lower nozzles 31 and 32 discharge the processing liquid at a high flow rate while the upper nozzle 33 is discharging the processing liquid toward the periphery of the substrate W, the processing liquid discharged from the upper nozzle 33 is suppressed from reaching the bottom surface of the substrate W, so that particles can be suppressed from adhering to the gas discharge ring 15 or the first holder 11.

In addition, it is desirable to reduce a discharge flow rate of the gas from the gas discharge ring 15 while the upper nozzle 33 is discharging the processing liquid toward the periphery of the substrate W, as compared to a discharge flow rate of the gas while the friction body 50 is rubbing the central portion of the bottom surface of the substrate W. As the gas discharge ring 15 discharges the gas at a high flow rate while the friction body 50 is rubbing the central portion of the bottom surface of the substrate W, the processing liquid discharged from the lower nozzles 31 and 32 can be suppressed from adhering to the gas discharge ring 15 or the first holder 11, so that particles can be suppressed from adhering to the gas discharge ring 15 or the first holder 11.

So far, the exemplary embodiment of the substrate processing apparatus and the substrate processing method according to the present disclosure have been described. However, the present disclosure is not limited to the above-described exemplary embodiment or the like. Various changes, corrections, replacements, addition, deletion and combinations may be made within the scope of the claims, and all of these are included in the scope of the inventive concept of the present disclosure.

According to the exemplary embodiment, it is possible to remove the dirt of the holder.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus comprising a processor configured to process a substrate with a processing liquid, the processor having a holder configured to hold the substrate horizontally, the holder including a first holder configured to come into contact with a center of a bottom surface of the substrate, and the processor having a rotation driver configured to rotate the first holder around a vertical rotation axis, the substrate processing apparatus comprising:
a charging member configured to charge a second substrate prepared separately from the substrate; and
a controller configured to perform bringing the second substrate charged by the charging member into contact with the first holder.

2. The substrate processing apparatus of claim 1,
wherein the charging member includes a friction body configured to rub a bottom surface of the second substrate held by the holder.

3. The substrate processing apparatus of claim 2, further comprising:
a lower nozzle configured to supply an alkaline aqueous solution between the friction body and the second substrate held by the holder.

4. The substrate processing apparatus of claim 3,
wherein the holder includes a second holder configured to come into contact with the bottom surface of the second substrate at an outer side than the first holder in a diametrical direction of the substrate, and
the controller performs:
rubbing a center of the bottom surface of the second substrate with the friction body while holding the second substrate horizontally by the second holder;
supplying the alkaline aqueous solution to the bottom surface of the second substrate continuously from before a start of the rubbing until after an end of the rubbing;
drying the bottom surface of the second substrate with a gas after the supplying of the alkaline aqueous solution; and
bringing the first holder into contact with the center of the bottom surface of the second substrate after the drying.

5. The substrate processing apparatus of claim 3,
wherein the holder includes a third holder configured to hold a periphery of the substrate, and
the controller performs:
rubbing a center of the bottom surface of the second substrate with the friction body while holding the second substrate horizontally by the third holder;
supplying the alkaline aqueous solution to the bottom surface of the second substrate continuously from before a start of the rubbing until after an end of the rubbing;
drying the bottom surface of the second substrate with a gas after the supplying of the alkaline aqueous solution; and
bringing the first holder into contact with the center of the bottom surface of the second substrate after the drying.

6. The substrate processing apparatus of claim 1, further comprising:
a storage configured to store the second substrate therein; and
a transferrer configured to transfer the second substrate between the storage and the processor,
wherein the charging member charges the second substrate in the storage.

7. The substrate processing apparatus of claim 1,
wherein the second substrate has an oxide film on at least a bottom surface thereof.

8. The substrate processing apparatus of claim 1,
wherein the holder includes multiple elevating pins provided around the first holder, and
the controller brings the second substrate charged by the charging member into contact with the multiple elevating pins.

9. A substrate processing apparatus, comprising:
a first holder configured to come into contact with a center of a bottom surface of a substrate and hold the substrate horizontally;
a rotation driver configured to rotate the first holder around a vertical rotation axis;
an upper nozzle configured to supply a processing liquid to a top surface of the substrate held by the first holder;
a lower nozzle configured to supply a processing liquid to the bottom surface of the substrate held by the first holder;
a gas discharger provided at an inner side than the lower nozzle in a diametrical direction of the substrate and an outer side than the first holder in the diametrical direction of the substrate, and configured to discharge a gas toward the bottom surface of the substrate held by the first holder;
a cup surrounding a periphery of the substrate held by the first holder; and
a wall member provided below the substrate held by the first holder, and configured to block the processing liquid discharged from the upper nozzle toward the periphery of the substrate from heading toward the first holder,
wherein the wall member is provided at an inner side than the periphery of the substrate held by the first holder in the diametrical direction of the substrate and an outer side than the gas discharger in the diametrical direction of the substrate.

10. A substrate processing method of processing a substrate by using a substrate processing apparatus,
wherein the substrate processing apparatus comprises a processor configured to process the substrate with a processing liquid, the processor has a holder configured to hold the substrate horizontally, the holder includes a first holder configured to come into contact with a center of a bottom surface of the substrate, and the processor has a rotation driver configured to rotate the first holder around a vertical rotation axis, and
wherein the substrate processing method comprises:
charging a second substrate provided separately from the substrate; and
bringing the charged second substrate into contact with the first holder.

11. The substrate processing method of claim 10,
wherein the charging of the second substrate includes rubbing a bottom surface of the second substrate held by the holder with a friction body.

12. The substrate processing method of claim 11, further comprising:
supplying an alkaline aqueous solution between the friction body and the second substrate held by the holder.

13. The substrate processing method of claim 12,
wherein the holder includes a second holder configured to come into contact with the bottom surface of the second substrate at an outer side than the first holder in a diametrical direction of the substrate, and
wherein the substrate processing method comprises:
rubbing a center of the bottom surface of the second substrate with the friction body while holding the second substrate horizontally by the second holder;
supplying the alkaline aqueous solution to the bottom surface of the second substrate continuously from before a start of the rubbing until after an end of the rubbing;
drying the bottom surface of the second substrate with a gas after the supplying of the alkaline aqueous solution; and
bringing the first holder into contact with the center of the bottom surface of the second substrate after the drying.

14. The substrate processing method of claim 12,
wherein the holder includes a third holder configured to hold a periphery of the substrate, and
wherein the substrate processing method comprises:
rubbing a center of the bottom surface of the second substrate with the friction body while holding the second substrate horizontally by the third holder;
supplying the alkaline aqueous solution to the bottom surface of the second substrate continuously from before a start of the rubbing until after an end of the rubbing;
drying the bottom surface of the second substrate with a gas after the supplying of the alkaline aqueous solution; and
bringing the first holder into contact with the center of the bottom surface of the second substrate after the drying.

15. The substrate processing method of claim 10,
wherein the substrate processing apparatus further comprises a storage configured to store the second substrate therein, and a transferrer configured to transfer the second substrate between the storage and the processor, and
wherein the substrate processing method comprises charging the second substrate in the storage.

16. The substrate processing method of claim 10,
wherein the second substrate has an oxide film on at least a bottom surface thereof.

17. The substrate processing method of claim 10,
wherein the holder includes multiple elevating pins provided around the first holder, and
wherein the substrate processing method comprises bringing the charged second substrate into contact with the elevating pins.

18. A substrate processing method comprising processing a substrate by using a substrate processing apparatus as claimed in claim 9.
